(19) United States
(12) Patent Application Publication
(10) Pub. No.: US 2026/0344017 A1
(43) Pub. Date: Oct. 29, 2026

(54) SEMICONDUCTOR DEVICE

(71) Applicant: Renesas Electronics Corporation, Tokyo (JP)

(72) Inventor: Hiroto NISHIZAWA, Tokyo (JP)

(21) Appl. No.: 19/562,093

(22) Filed: Mar. 10, 2026

(30) Foreign Application Priority Data
Apr. 23, 2025 (JP) 2025-071908

(51) Int. Cl. H10D 84/00; H10D 64/27

(52) U.S. Cl. CPC H10D 84/143; H10D 64/518

(57) ABSTRACT

A semiconductor device includes a diode, a first sense transistor and a second sense transistor. The first sense transistor is disposed between the diode and the second sense transistor. A source region of the first sense transistor is electrically isolated from a source region of the second sense transistor.

### CROSS-REFERENCE TO RELATED APPLICATIONS

The disclosure of Japanese Patent Application No. 2025-071908 filed on Apr. 23, 2025, including the specification, drawings and abstract is incorporated herein by reference in its entirety.

### BACKGROUND

This disclosure relates to semiconductor devices. This disclosure relates to semiconductor devices, which include sense transistors for detecting the current flowing through the main transistor, for example.

There are disclosed techniques listed below.

Patent Document 1 Japanese Unexamined Patent Application Publication No. 10-326897

Patent Document 1 describes a technique that improves the detection accuracy of the current flowing through the main cell by reducing the difference in characteristics between the main cell and the current detection cell.

### SUMMARY

For example, there are semiconductor devices that include main transistors and sense transistors. The main transistor causes current to flow through the load circuit. The sense transistor detects the current flowing through the main transistor.

The current flowing through the main transistor is large. Therefore, it is difficult to directly detect the current flowing through the main transistor. Hence, a part of the current flowing through the main transistor is diverted to the sense transistor. The current flowing through the sense transistor is smaller than the current flowing through the main transistor. This implies that the current flowing through the sense transistor is easier to detect compared to that of the main transistor. Thus, the current flowing through the main transistor is indirectly detected based on the current flowing through the sense transistor. In this case, to detect the current of the main transistor with high accuracy, it is necessary to minimize the difference in characteristics between the main transistor and the sense transistor.

From the above, it is desirable to minimize the characteristic differences between the main transistor and the sense transistor to accurately detect the current of the main transistor.

Other objects and novel features will become apparent from the description of this specification and the accompanying drawings.

In one embodiment, a first transistor is disposed between a diode and a second transistor. The first transistor includes a first gate electrode and a first source region. The second transistor includes a second gate electrode and a second source region. The first gate electrode and the second gate electrode are electrically connected to each other. The first source region and the second source region are electrically isolated from each other.

In one embodiment, a first transistor includes a first gate electrode and a first source region. A second transistor includes a second gate electrode and a second source region. The first transistor has a lower threshold voltage than the second transistor. The first gate electrode and the second gate electrode are electrically connected to each other. The first source region and the second source region are electrically isolated from each other.

According to one embodiment, the difference in characteristics between the main transistor and the sense transistor can be reduced. As a result, by detecting the current flowing through the sense transistor, the current flowing through the main transistor can be detected with high accuracy.

### BRIEF DESCRIPTION OF THE DRAWINGS

FIG. 1 is a circuit diagram showing a configuration example of a load driving circuit.

FIG. 2 is a plan view showing a part of a semiconductor chip in related technology.

FIG. 3 is a cross-sectional view of the semiconductor chip along line A-A in FIG. 2.

FIG. 4 is a cross-sectional view of the semiconductor chip along line B-B in FIG. 2.

FIG. 5 is a circuit diagram showing the configuration of a load driving circuit in the embodiment.

FIG. 6 is a plan view showing the configuration of the semiconductor chip in the embodiment.

FIG. 7 is an enlarged view near the sense transistor formation region in the embodiment.

FIG. 8 is a cross-sectional view of the semiconductor chip along line A-A in FIG. 7.

FIG. 9 is an enlarged view near the sense transistor formation region in a modified example.

### DETAILED DESCRIPTION

In all drawings for explaining the embodiments, as a rule, identical reference numerals are assigned to identical members, and repeated descriptions thereof are omitted. Note that even plan view may be hatched for the sake of clarity.

Note that in this specification, the expressions that "A equals B" or "A is the same as B" do not intend A and B to be physically identical. That is, the expressions that "A equals B" or "A is the same as B" in this specification allow for errors due to manufacturing variations.

### Configuration Example of Load Driving Circuit

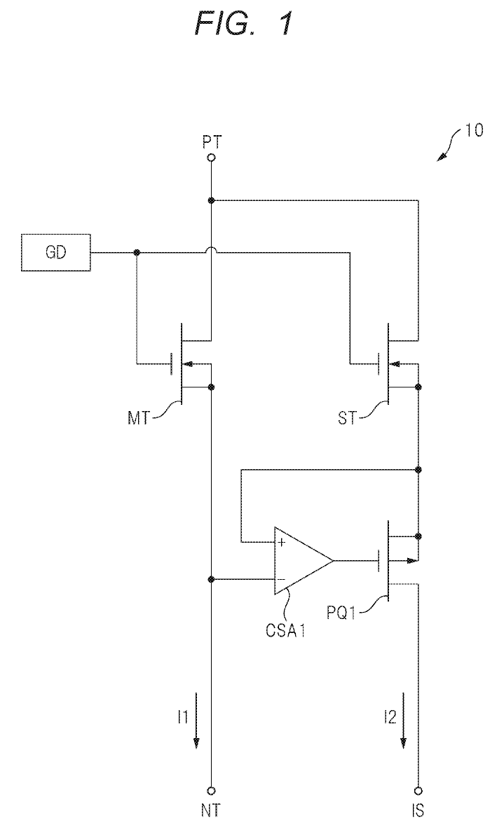

FIG. 1 is a circuit diagram showing a configuration example of load driving circuit 10.

The load driving circuit 10 includes a positive terminal PT, negative terminal NT, sense terminal IS, gate driver GD, main transistor MT, sense transistor ST, current sensing amplifier CSA, and p-type transistor PQ1.

The load driving circuit 10 allows current to flow into the load circuit. In FIG. 1, the load circuit is not shown. The load circuit is connected between the positive terminal PT and the negative terminal NT.

A positive potential is applied to the positive terminal PT. A potential lower than the positive potential applied to the positive terminal PT is applied to the negative terminal NT. For example, a ground potential (0V) or a negative potential is applied to the negative terminal NT.

The main transistor MT is configured to supply current to the load circuit. The main transistor MT is electrically connected to the positive terminal PT and the negative terminal NT. The main transistor MT is, for example, an n-type transistor. The main transistor MT includes a gate, source, and drain. The drain (drain electrode DE) of the main transistor MT is electrically connected to the positive terminal PT. The source (source region SR1 and body contact region BC1) of the main transistor MT is electrically connected to the negative terminal NT. The gate of the main transistor MT is electrically connected to the gate driver GD.

The sense transistor ST is configured to indirectly detect the current flowing through the main transistor MT. The sense transistor ST is electrically connected to the positive terminal PT. The sense transistor ST is, for example, an n-type transistor. The sense transistor ST includes a gate, source, and drain. The drain (drain electrode DE) of the sense transistor ST is electrically connected to the positive terminal PT. The gate of sense transistor ST is electrically connected to the gate driver GD. The source (source region SR and body contact region BC) of the sense transistor is electrically connected to the sense terminal IS.

The p-type transistor PQ1 is connected between sense transistor ST and sense terminal IS. The p-type transistor PQ1 includes a gate, source, and drain. The source of the p-type transistor PQ1 is electrically connected to the source of the sense transistor ST. The drain of the p-type transistor PQ1 is electrically connected to the sense terminal IS.

The current sensing amplifier CSA1 has a positive input terminal, a negative input terminal, and an output terminal. The negative input terminal of the current sensing amplifier CSA1 is electrically connected to the source of the main transistor MT. The positive input terminal of the current sensing amplifier CSA1 is electrically connected to the source of the sense transistor ST. The output terminal of the current sensing amplifier CSA1 is electrically connected to the gate of the p-type transistor PQ1.

"I1" shows the current flowing through the main transistor MT. "I2" shows the current flowing through the sense transistor ST.

The source potential of the main transistor MT is input to the negative input terminal of the current sensing amplifier CSA1. The source potential of the sense transistor ST is input to the positive input terminal of the current sensing amplifier CSA1. The output terminal of the current sensing amplifier CSA1 outputs a voltage signal based on the potential difference between the source potential of the main transistor MT and the source potential of the sense transistor ST. This voltage signal is supplied to the gate electrode of the p-type transistor PQ1. The current sensing amplifier CSA1 and p-type transistor PQ1 control the potential difference between the source potentials of the main transistor MT and the sense transistor ST to approach zero.

### Need for Sent Transistor

When supplying current from the load driving circuit 10 to the load circuit, current flows through the main transistor MT. The current flowing through the main transistor MT is very large. For example, the current flowing through the main transistor MT is about 10 A to 20 A.

Here, using the current flowing through the main transistor MT as the directly detected current is considered. When feedback control of the current flowing through the main transistor MT is based on the detected current, the detected current must be routed through wiring to the microcomputer used for the feedback control. Considering the allowable current range for the microcomputer and wiring, using a very large detected current is difficult.

Thus, the current flowing through the sense transistor ST is used as detected current to indirectly detect the current flowing through the main transistor MT. In this case, the current flowing through the sense transistor ST is smaller than the current flowing through the main transistor MT. Therefore, the detected current flowing through the sense transistor ST falls in the allowable current range for microcomputers and wiring. Consequently, feedback control of the current flowing through the main transistor MT can be achieved by using detected current in the allowable range for the microcomputer and wiring.

In the load driving circuit 10 shown in FIG. 1, "I2" is smaller than "I1". The microcomputer detects "I1" based on "I2". "I2" is input to the microcomputer via the sense terminal IS, for example.

The microcomputer stores in advance the ratio (sense ratio) of the current flowing through the main transistor MT to the current flowing through the sense transistor ST. From this, the microcomputer can calculate "I1" by computing the product of the "sense ratio" and "I2". In this way, by using the sense transistor ST, the current flowing through the main transistor MT can be indirectly detected.

### Consideration for Improvement

In order to accurately detect the current flowing through the main transistor MT using the current flowing through the sense transistor ST, it is desirable that the current characteristics of the main transistor MT and the current characteristics of the sense transistor ST match to each other.

Specifically, the current characteristics of a transistor refer to the threshold voltage (Vth) of the transistor. In this specification, the threshold voltage of a transistor is defined as the gate voltage at the moment when the drain current becomes100μA as the gate voltage is increased under a condition where the voltage between the source and the drain is 10V (constant current method).

The difference between the threshold voltage of the main transistor MT and the threshold voltage of the sense transistor ST is referred to as "ΔVth". The "sense ratio" is calculated based on the assumption that the threshold voltage of the main transistor MT matches the threshold voltage of the sense transistor ST ("ΔVth" = 0). Therefore, in an actual device, when "ΔVth" becomes greater than 0, the actual current "I1" deviates from the current value calculated from the product of the "sense ratio" and "I2". As a result, it is not possible to accurately detect the current flowing through the main transistor MT using the current flowing through the sense transistor ST. Therefore, it is necessary to reduce "ΔVth".

To accurately detect the current of the main transistor MT using the sense transistor ST, it is desirable to minimize the difference in threshold voltages between the main transistor MT and the sense transistor ST.

Regarding this point, the inventor newly discovered that "ΔVth" increases due to the structure of the device in real-world applications. Below, this will be explained using related technology.

### Related Technology

In this specification, "related technology" refers to technology that is not well-known but addresses problems discovered by the inventor, serving as the basis for this disclosure.

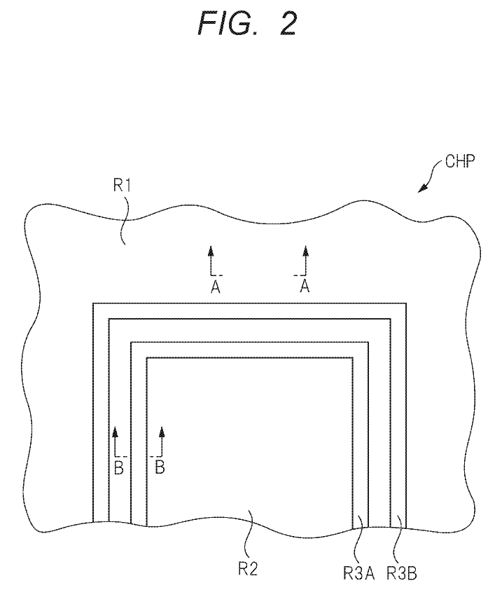

FIG. 2 is a plan view showing a portion of the semiconductor chip CHP in the related technology.

The semiconductor chip CHP has a main transistor formation region R1, a sense transistor formation region R2, a diode formation region R3A, and a diode formation region R3B.

The main transistor is formed in the main transistor formation region R1. The sense transistor is formed in the sense transistor formation region R2. A pn junction diode is formed in the diode formation region R3A. A pn junction diode is formed in the diode formation region R3B.

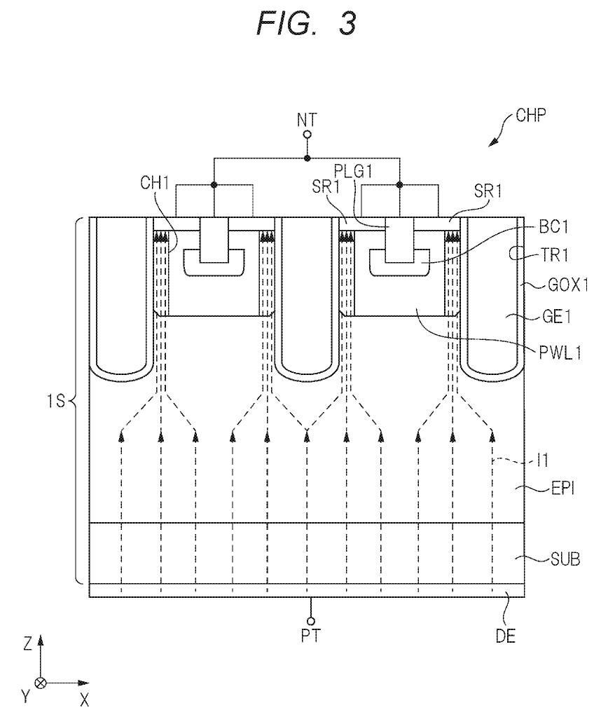

FIG. 3 is a cross-sectional view of the semiconductor chip CHP along line A-A of FIG. 2.

FIG. 3 shows the cross-sectional structure of the main transistor.

The semiconductor chip CHP has a drain electrode DE and a semiconductor substrate 1S. The semiconductor substrate 1S has a substrate SUB, an epitaxial layer EPI, a trench TR1, a gate insulating film GOX1, and a gate electrode GE1. The semiconductor substrate 1S has a p-type well PWL1, a body contact region BC1, a source region SR1, and a plug PLG1.

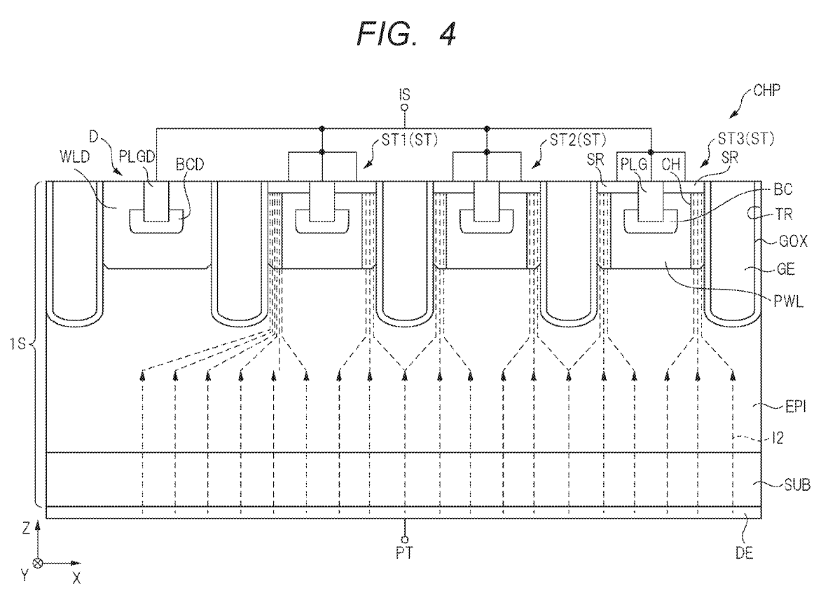

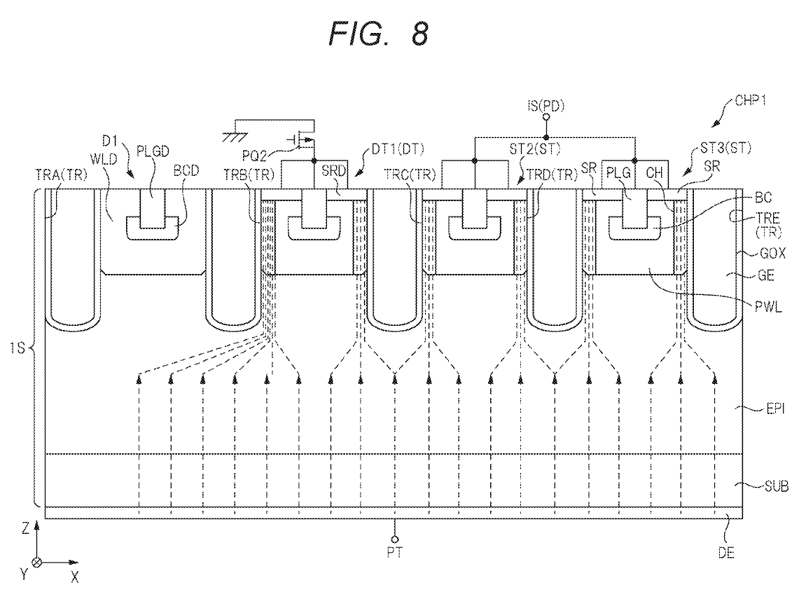

In detail, an interlayer insulating film is formed on the semiconductor substrate 1S, and the plug PLG1 penetrates through the interlayer insulating film. Part of this plug PLG1 reaches into the p-type well PWL1. That is, in FIG. 3, only the portion of plug PLG1 formed in the semiconductor substrate 1S is illustrated. This is also similar in FIGS. 4, and 8.

The semiconductor substrate 1S has an upper surface and a lower surface. The drain electrode DE is formed on the lower surface of the semiconductor substrate 1S. The substrate SUB has an upper surface and a lower surface. The lower surface of the substrate SUB is the lower surface of the semiconductor substrate 1S. An epitaxial layer EPI is formed on the upper surface of the substrate SUB. A plurality of trenches TR1 are formed in the epitaxial layer EPI. The plurality of trenches TR1 are disposed at the upper surface of the semiconductor substrate 1S. The plurality of trenches TR1 are spaced apart from each other. The plurality of trenches TR1 are arranged in the X direction. In each of the plurality of trenches TR1, gate electrodes GE1 are formed via gate insulating films GOX1.

The p-type well PWL1 is formed in the epitaxial layer EPI. The p-type well PWLis disposed between trenches TR1 adjacent to each other. A source region SR1 is formed in the p-type well PWL1. A body contact region BC1 is formed in the p-type well PWL1. The plug PLG1 is formed so as to be in contact with the source region SR1 and the body contact region BC1. The source region SR1 and the body contact region BC1 are electrically connected to each other via the plug PLG1.

In FIG. 3, for example, a main transistor in a state where a gate voltage exceeding the threshold voltage is applied to gate electrode GE1 is illustrated. In other words, FIG. 3 shows the main transistor in the on state. Therefore, channel CH1 is formed in the p-type well PWL1 in contact with the side surface of trench TR1. Thus, as shown by the dashed arrow in FIG. 3, current "I1" flows along the path from positive terminal PT, drain electrode DE, substrate SUB, epitaxial layer EPI, channel CH1, source region SR1, to negative terminal NT.

FIG. 4 is a cross-sectional view of the semiconductor chip CHP along line B-B of FIG. 2.

FIG. 4 shows the cross-sectional structure of the diode D and the sense transistor ST. The sense transistor ST includes a cell transistor ST1, a cell transistor ST2, and a cell transistor ST3. The cell transistor ST1 is disposed between diode D and cell transistor ST2.

The semiconductor chip CHP has a drain electrode DE, a substrate SUB, and an epitaxial layer EPI. The drain electrode DE is formed on the lower surface of the substrate SUB. The epitaxial layer EPI is formed on the upper surface of the substrate SUB.

The diode D is a pn junction diode. The diode D has a p-type well WLD, a body contact region BCD, and a plug PLGD. The p-type well WLD is formed in the epitaxial layer EPI. The p-type well WLD is disposed between trenches TR adjacent to each other. In the p-type well WLD, a body contact region BCD and a plug PLGD are formed. The epitaxial layer EPI is an n-type semiconductor layer. Conversely, the p-type well WLD is a p-type semiconductor region. Thus, a pn junction diode is formed by the epitaxial layer EPI and the p-type well WLD. The p-type well WLD and the body contact region BCD function as the anode region of diode D. In contrast, the part of the epitaxial layer EPI located under and in contact with the p-type well WLD functions as the cathode region of diode D.

The sense transistor ST has a p-type well PWL, a body contact region BC, a source region SR, a plug PLG, a trench TR, a gate insulating film GOX, and a gate electrode GE.

Each of the plurality of trenches TR is formed in the epitaxial layer EPI. Each of the plurality of trenches TR is disposed at the upper surface of the semiconductor substrate 1S. The gate electrodes GE are formed in the plurality of trenches TR via gate insulating films GOX,.

A p-type well PWL is formed in the epitaxial layer EPI. A source region SR is formed in the p-type well PWL. A body contact region BC is formed in the p-type well PWL. The plug PLG is formed so as to be in contact with the source region SR and the body contact region BC. The source region SR and the body contact region BC are electrically connected to each other via the plug PLG.

In FIG. 4, for example, the sense transistor ST is shown in a state where a gate voltage exceeding the threshold voltage is applied to the gate electrode GE. In other words, FIG. 4 shows the sense transistor ST in the on state. Therefore, channel CH is formed in the p-type well PWL that is in contact with the side surfaces of each of the plurality of trenches TR. Thus, as indicated by the dotted arrow in FIG. 4, current "I2" flows along the path from positive terminal PT, drain electrode DE, substrate SUB, epitaxial layer EPI, channel CH, source region SR, to sense terminal IS.

### Room for Improvement

In FIG. 4, in the on state of the sense transistor ST, a positive potential is supplied to the positive terminal PT. A potential lower than the positive terminal PT is supplied to the sense terminal IS. The p-type well WLD, functioning as the anode region of diode D, is electrically connected to the sense terminal IS. The epitaxial layer EPI, functioning as the cathode region of diode D, is electrically connected to the positive terminal PT. Therefore, in the on state of the sense transistor ST, a reverse bias is applied to diode D. Therefore, in the on-state of the sense transistor ST, no current flows through the diode D. Thus, as shown in FIG. 4, cell transistor ST1 adjacent to diode D receives not only the current flowing from the portion of the drain electrode DE located under the p-type well PWL of cell transistor ST1, but also the current flowing directly under diode D.

As a result, the current density of the current flowing through the channel CH of cell transistor ST1 is higher than the current density of the current flowing through the channel CH of cell transistor ST2. The current density of the current flowing through the channel CH of cell transistor ST1 is higher than the current density of the current flowing through the channel CH of cell transistor ST3.

The gate voltage applied to the gate electrode GE of cell transistor ST1 is the same as the gate voltage applied to the gate electrode GE of cell transistor ST2. The gate voltage applied to the gate electrode GE of cell transistor ST1 is the same as the gate voltage applied to the gate electrode GE of cell transistor ST3. In other words, the same gate voltage is applied to the gate electrode GE of each of the plurality of cell transistors forming the sense transistor ST.

Thus, despite the same gate voltage being applied, the current density flowing through channel CH of cell transistor ST1 is higher than the current density flowing through the channels CH of the other cell transistors. Therefore, the threshold voltage of cell transistor ST1 is lower than the threshold voltage of each of the other cell transistors.

In this way, the inventor has newly discovered that the threshold voltage of cell transistor ST1 adjacent to diode D is lower than the threshold voltage of each of the other cell transistors. As a result, the overall threshold voltage of the sense transistor ST decreases.

By a similar mechanism, it is considered that the threshold voltage of the cell transistors adjacent to the diode, among the plurality of cell transistors forming the main transistor MT, is lower than the threshold voltage of each of the other cell transistors. As a result, the overall threshold voltage of the main transistor MT also decreases.

In this regard, the number of cell transistors forming the main transistor MT is larger than the number of cell transistors forming the sense transistor ST. Therefore, the decrease in the overall threshold voltage of the sense transistor ST is larger than the decrease in the overall threshold voltage of the main transistor MT.

As a result, the difference between the threshold voltage of the main transistor MT and the threshold voltage of the sense transistor ST, denoted as "ΔVth", increases. When "ΔVth" becomes large, the discrepancy between the actual current value flowing through the main transistor MT and the estimated value calculated from the product of the "sense ratio" and the current flowing through the sense transistor ST becomes large. As a result, it becomes impossible to accurately detect the current flowing through the main transistor MT using the current flowing through the sense transistor ST.

Therefore, it is desired to reduce "ΔVth".

### Basic Concept

In FIG. 4, the source region SR of cell transistor ST1 is electrically connected to the source region SR of each of the other cell transistors. The source region SR of each of the other cell transistors and the source region SR of cell transistor ST1 are electrically connected to the sense terminal IS.

In this specification, "the other cell transistors" collectively refer to all cell transistors except for cell transistor ST1 among the plurality of cell transistors. Specifically, "the other cell transistors" do not include cell transistor ST1 but include at least cell transistor ST2 and cell transistor ST3.

In the basic concept of this disclosure, the source region SR of cell transistor ST1 is electrically isolated from the source region SR of each of "the other cell transistors". Cell transistor ST1 has a lower threshold voltage than each of "the other cell transistors".

In the basic concept, the source region SR of each of "the other cell transistors" is electrically connected to the sense terminal IS. However, in the basic concept, the source region SR of cell transistor ST1 is not electrically connected to the sense terminal IS. Thus, the source region SR of cell transistor ST1 is electrically isolated from the source region SR of each of "the other cell transistors".

As a result, "the other cell transistors" function as the sense transistor ST to detect the current flowing through the main transistor MT. Conversely, cell transistor ST1 does not function as the sense transistor ST to detect the current flowing through the main transistor MT. In this specification, cell transistor ST1, which does not function as a cell transistor forming the sense transistor ST, is referred to as a "dummy transistor".

In the basic concept, the cell transistor ST1 among the plurality of cell transistors forming the sense transistor ST is designated as the "dummy transistor". Thus, cell transistor ST1 is not used as the sense transistor ST for detecting the current flowing through the main transistor MT. In other words, cell transistor ST1, which has a lower threshold voltage than each of "the other cell transistors", becomes the dummy transistor.

As a result, the variation in the threshold voltage of the sense transistor ST is reduced. Consequently, the threshold voltage of the sense transistor ST becomes close the threshold voltage of the main transistor MT. Therefore, "ΔVth" can be reduced.

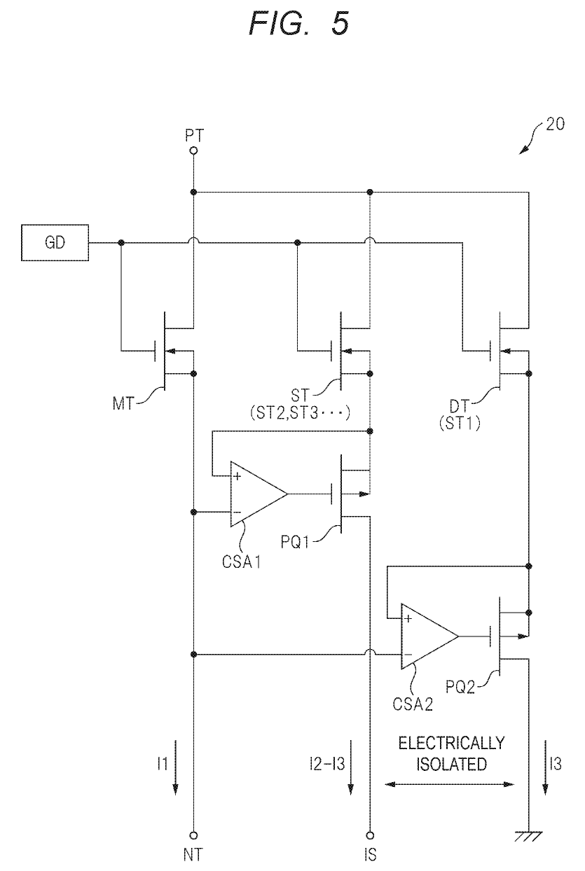

FIG. 5 is a circuit diagram illustrating the configuration of a load driving circuit 20 that realizes the basic concept.

The load driving circuit 20 includes a positive terminal PT, a negative terminal NT, a sense terminal IS, a gate driver GD, a main transistor MT, a sense transistor ST, and a dummy transistor DT. The load driving circuit 20 includes a current sensing amplifier CSA1, a p-type transistor PQ1, a current sensing amplifier CSA2, and a p-type transistor PQ2.

The load driving circuit 20 includes a configuration similar to that of load driving circuit 10, and further includes a dummy transistor DT, the current sensing amplifier CSA2, and a p-type transistor PQ2. Hereafter, the description of common points between load driving circuit 20 and load driving circuit 10 is omitted, and differences between load driving circuit 20 and load driving circuit 10 are explained.

In FIG. 5, "I1" is the current flowing through plurality of main transistors MT. "I2-I3" is the current flowing through the sense transistor ST.

The dummy transistor DT is configured not to indirectly detect the current flowing through the main transistor MT. The dummy transistor DT is electrically connected to the positive terminal PT. The dummy transistor DT is, for example, an n-type transistor. The dummy transistor DT has a gate, source, and drain. The drain (drain electrode DE) of dummy transistor DT is electrically connected to the positive terminal PT. The gate of dummy transistor DT is electrically connected to the gate driver GD.

The p-type transistor PQ2 is connected between the dummy transistor DT and ground. The p-type transistor PQ2 has a gate, source, and drain. The source of p-type transistor PQ2 is electrically connected to the source of dummy transistor DT. The drain of p-type transistor PQ2 is electrically connected to ground.

Current sensing amplifier CSA2 has a positive input terminal, a negative input terminal, and an output terminal. The negative input terminal of current sensing amplifier CSA2 is electrically connected to the source of the main transistor MT. The positive input terminal of current sensing amplifier CSA2 is electrically connected to the source of dummy transistor DT. The output terminal of current sensing amplifier CSA2 is electrically connected to the gate of the p-type transistor PQ2.

"I3" is the current flowing through dummy transistor DT.

The source potential of the main transistor MT is input to the negative input terminal of current sensing amplifier CSA2. The source potential of dummy transistor DT is input to the positive input terminal of current sensing amplifier CSA2. A voltage signal based on the potential difference between the source potential of the main transistor MT and the source potential of dummy transistor DT is output from the output terminal of current sensing amplifier CSA2. The voltage signal is supplied to the gate electrode of the p-type transistor PQ2. As a result, the potential difference between the source potential of the main transistor MT and the source potential of dummy transistor DT is controlled to approach zero by current sensing amplifier CSA2 and p-type transistor PQ2.

As shown in FIG. 5, the gate of the main transistor MT, the gate of the sense transistor ST, and the gate of the dummy transistor DT are electrically connected to each other. The gate of the main transistor MT and the gate of the dummy transistor DT are electrically connected to each other. The gate of the sense transistor ST and the gate of the dummy transistor DT are electrically connected to each other.

The source of sense transistor ST is electrically connected to the sense terminal IS via a p-type transistor PQ1. The source of dummy transistor DT is electrically connected to ground via a p-type transistor PQ2.

The sense terminal IS and the ground are electrically isolated from each other. Therefore, in the load driving circuit 20 shown in FIG. 5, the source of dummy transistor DT is electrically isolated from the source of sense transistor ST. From this, the load driving circuit 20 embodies the basic concept.

### First Embodiment

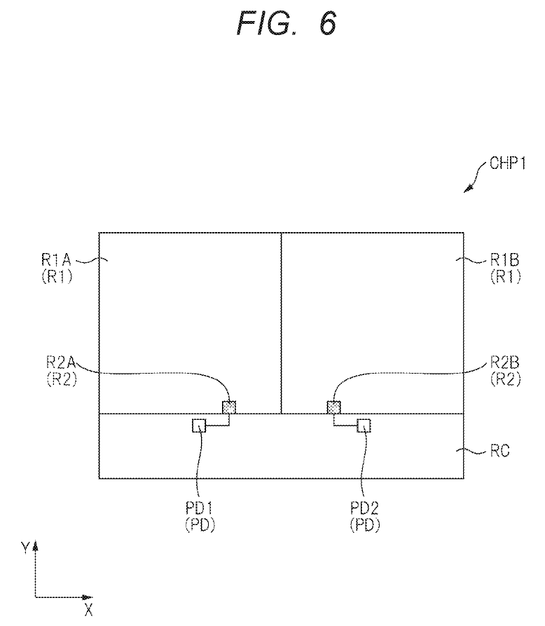

FIG. 6 is a plan view illustrating the configuration of semiconductor chip CHP1 according to the embodiment.

The semiconductor chip CHP1 has a main transistor formation region R1A, a main transistor formation region R1B, a sense transistor formation region R2A, a sense transistor formation region R2B, and a control circuit formation region RC.

If differentiation between the main transistor formation region R1A and the main transistor formation region R1B is unnecessary, they are described as main transistor formation region R1.

If differentiation between the sense transistor formation region R2A and the sense transistor formation region R2B is unnecessary, they are described as sense transistor formation region R2.

The main transistor MT is formed in main transistor formation region R1. The main transistor MT is configured by, for example, a field effect transistor. That is, main transistor MT has a gate electrode, source region, and drain region.

The sense transistor ST is formed in sense transistor formation region R2. The sense transistor ST is configured by, for example, a field effect transistor. That is, sense transistor ST has a gate electrode, source region, and drain region.

Although not shown in FIG. 6, the region adjacent to part of the sense transistor formation region R2 has dummy transistor DT formed there, as shown in FIG. 5. The dummy transistor DT is a cell transistor ST1 that does not function as sense transistor ST. Dummy transistor DT is configured by, for example, a field effect transistor. That is, dummy transistor DT has a gate electrode, source region, and drain region.

As illustrated in FIG. 6, the size of main transistor MT in plan view is larger than the size of sense transistor ST.

The gate length of dummy transistor DT is equal to the gate length of sense transistor ST. The gate width of dummy transistor DT is equal to or smaller than the gate width of sense transistor ST.

The gate length of main transistor MT is equal to the gate length of sense transistor ST. The gate length of main transistor MT is equal to the gate length of dummy transistor DT. The gate width of main transistor MT is greater than the gate width of sense transistor ST. The gate width of main transistor MT is greater than gate width of dummy transistor DT.

A control circuit is formed in the control circuit formation region RC.

The control circuit is configured to control the operation of main transistor MT, dummy transistor DT, and sense transistor ST. Specifically, the control circuit is configured to control the switching operations of main transistor MT, dummy transistor DT, and sense transistor ST. Switching operation refers to the transition between on-operation and off-operation.

The control circuit includes, for example, current sensing amplifier CSA1, current sensing amplifier CSA2, p-type transistor PQ1 and p-type transistor PQ2 (see FIG. 5). The p-type transistor PQ1 is configured by, for example, a field effect transistor. That is, p-type transistor PQ1 has a gate electrode, source region, and drain region. The p-type transistor PQ2 is configured by, for example, a field effect transistor. That is, p-type transistor PQ2 has a gate electrode, source region, and drain region.

A pad PD1 and a pad PD2 are formed in the control circuit formation region RC.

If differentiation between pad PD1 and pad PD2 is unnecessary, they are described as pad PD. The pad PD is an external connection terminal.

The pad PD1 is electrically connected to sense transistor ST, which is formed in sense transistor formation region R2A, via wiring. The pad PD2 is electrically connected to sense transistor ST, which is formed in sense transistor formation region R2B, via wiring.

In the embodiment, the current detection part is formed on a semiconductor chip separated from semiconductor chip CHP1. The current detection part is configured to indirectly detect the current flowing through main transistor MT based on the current flowing through sense transistor ST. Specifically, the current detection part calculates the product of the "sense ratio" and the current flowing through sense transistor ST to detect the current flowing through main transistor MT.

The current detection part can be realized, for example, with a microcomputer formed on a semiconductor chip separated from semiconductor chip CHP1. In this case, the separate semiconductor chip is connected to pad PD of semiconductor chip CHP1 by bonding wire. Thus, the current flowing through sense transistor ST is input to the microcomputer via pad PD and bonding wire. As a result, the microcomputer can detect the current of main transistor MT based on the "sense ratio" and the input current.

However, the current detection part may be formed as a current detection circuit in the control circuit formation region RC of semiconductor chip CHP1. In this case, the pad PD for supplying the current flowing through sense transistor ST to an external circuit need not be formed.

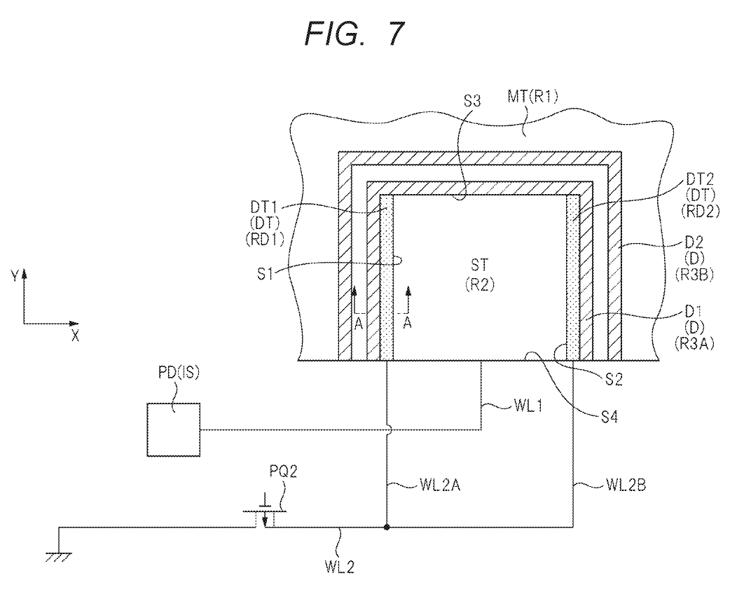

FIG. 7 is an enlarged view of the vicinity of sense transistor formation region R2.

The planar shape of sense transistor formation region R2 is rectangular. The rectangle has a side S1, a side S2, a side S3, and a side S4. The side S2 is disposed opposite the side S1. The side S3 intersects with the side S1. The side S3 intersects with the side S2. The side S4 is disposed opposite the side S3.

The side S1 extends in the Y direction. The side S2 extends in the Y direction. The side S3 extends in the X direction intersecting the Y direction. The side S4 extends in the X direction.

The dummy transistor formation region RD1 is in contact with the side S1. The dummy transistor DT1 is formed in dummy transistor formation region RD1.

The dummy transistor formation region RD2 is in contact with the side S2. The dummy transistor DT2 is formed in dummy transistor formation region RD2.

If differentiation between dummy transistor DT1 and dummy transistor DT2 is unnecessary, they are described as dummy transistor DT.

The diode formation region R3A is in contact with dummy transistor formation region RD1. The diode formation region R3A is in contact with dummy transistor formation region RD2. The diode formation region R3A is in contact with the side S3. The diode D1 is formed in diode formation region R3A. The diode D1 is formed to suppress parasitic bipolar operation in each sense transistor ST. The diode D1 is formed to suppress parasitic bipolar operation in dummy transistor DT.

The diode formation region R3B is located outside of diode formation region R3A. The diode formation region R3B is planar-separated from diode formation region R3A.

The diode D2 is formed in diode formation region R3B. The diode D2 is formed to suppress parasitic bipolar operation in main transistor MT. If differentiation between diode D1 and diode D2 is unnecessary, they are described as diode D. In plan view, diode D surrounds dummy transistor DT and sense transistor ST.

The main transistor formation region R1 is located outside of diode formation region R3B. The main transistor formation region R1 is in contact with diode formation region R3B.

The sense transistor ST is electrically connected to pad PD, via a wiring line WL1, for example. The wiring line WL1 is, for example, a first layer wiring line among multilayer wiring. The first layer wiring line is the lowest layer wiring line among multilayer wiring.

The dummy transistor DT1 is electrically connected to a wiring line WL2A, for example. The wiring line WL2A is formed of a combination of first layer wiring line and second layer wiring line to avoid contact with wiring WL1. The second layer wiring line is disposed at the upper layer of the first layer wiring line.

The dummy transistor DT2 is electrically connected to a wiring line WL2B, for example. The wiring line WL2B is, for example, the first layer wiring line.

The wiring line WL2A and the wiring line WL2B are connected to each other. That is, the wiring line WL2A and the wiring line WL2B are connected to the wiring line WL2. The wiring line WL2 is electrically connected to ground via a p-type transistor PQ2. Thus, the dummy transistor DT is electrically connected to ground. Each of the dummy transistors DT is not electrically connected to the pad PD.

As shown in FIG. 7, in the X direction, the sense transistor ST is disposed between the dummy transistor DT1 and the dummy transistor DT2. The gate electrode of sense transistor ST, the gate electrode of dummy transistor DT1, and the gate electrode of dummy transistor DT2 are electrically connected to each other. The source region of sense transistor ST is electrically isolated from the source region of dummy transistor DT1. The source region of sense transistor ST is electrically isolated from the source region of dummy transistor DT2.

FIG. 8 is a cross-sectional view of the semiconductor chip CHP1 along line A-A of FIG. 7.

FIG. 8 shows the cross-sectional structures of diode D1, dummy transistor DT1, and sense transistor ST. In FIG. 8, the cell transistor ST2 and the cell transistor ST3 are illustrated as forming the sense transistor ST.

The semiconductor chip CHP1 has a drain electrode DE, a substrate SUB, and an epitaxial layer EPI. The drain electrode DE is formed on the lower surface of the substrate SUB. The epitaxial layer EPI is formed on the upper surface of the substrate SUB.

The plurality of trenches TR are formed in the epitaxial layer EPI. The plurality of trenches TR are arranged at the upper surface of the semiconductor substrate 1S. The plurality of trenches TR are spaced apart in the X direction. Each of the plurality of trenches TR extends in the Y direction. In each of the plurality of trenches TR, a gate electrode GE is formed via the gate insulating film GOX.

The plurality of trenches TR include a trench TRA, a trench TRB, a trench TRC, a trench TRD, and a trench TRE.

Note, if there is no need to distinguish between the trench TRA, the trench TRB, the trench TRC, the trench TRD, and the trench TRE, they are described as trench TR.

The trench TRA and the trench TRB are adjacent to each other. The trench TRB and the trench TRC are adjacent to each other. The trench TRC and the trench TRD are adjacent to each other. The trench TRD and the trench TRE are adjacent to each other.

The trench TRB is disposed between the trench TRA and the trench TRC. The trench TRC is disposed between the trench TRB and the trench TRD. The trench TRD is disposed between the trench TRC and the trench TRE.

The diode D1 is formed between the trench TRA and the trench TRB. The diode D1 is a pn-junction diode. The diode D1 has a p-type well WLD, a body contact region BCD, and a plug PLGD.

The p-type well WLD is formed in the epitaxial layer EPI. The p-type well WLD is disposed between the trench TRA and the trench TRB adjacent to each other.

The body contact region BCD and the plug PLGD are formed in the p-type well WLD. The epitaxial layer EPI is an n-type semiconductor layer. In contrast, the p-type well WLD is a p-type semiconductor region. Thus, a pn-junction diode is formed between the epitaxial layer EPI and the p-type well WLD.

The p-type well WLD and the body contact region BCD function as the anode region of the diode D1. The anode region of the diode D1 is disposed between the trench TRA and the trench TRB. The anode region of the diode D1 is in contact with the trench TRA and the trench TRB. In contrast, the epitaxial layer EPI, in contact with the p-type well WLD, functions as the cathode region of diode D1.

The dummy transistor DT1 has a p-type well PWL, a body contact region BC, a source region SRD, a plug PLG, a trench TRB, a trench TRC, a gate insulating film GOX, and a gate electrode GE. In the X direction, the dummy transistor DT1 is disposed between the diode D1 and the cell transistor ST2.

Similarly, the dummy transistor DT2 has a p-type well PWL, a body contact region BC, a source region SRD, a plug PLG, a trench TRB, a trench TRC, a gate insulating film GOX, and a gate electrode GE.

The substrate SUB and the epitaxial layer EPI function as the drain region of the dummy transistor DT1. Similarly, the substrate SUB and the epitaxial layer EPI function as the drain region of the dummy transistor DT2.

The trench TRB is formed in the epitaxial layer EPI. The gate electrode GE is formed in the trench TRB via the gate insulating film GOX. The trench TRC is formed in the epitaxial layer EPI. The gate electrode GE is formed in the trench TRC via the gate insulating film GOX.

The p-type well PWL is formed in the epitaxial layer EPI. The source region SRD is formed in the p-type well PWL. The source region SRD is disposed between the trench TRB and the trench TRC. The source region SRD is formed in the opposite position of the anode region against the trench TRB. The source region SRD of the dummy transistor DT1 is in contact with the trench TRB and the trench TRC.

The body contact region BC is formed in the p-type well PWL. The plug PLG is formed to be in contact with the source region SRD and the body contact region BC. The plug PLG is formed to penetrate through the source region SRD and reach the body contact region BC. The source region SRD and the body contact region BC are electrically connected to the plug PLG. The source region SRD and the body contact region BC are electrically connected to the ground via the p-type transistor PQ2.

The sense transistor ST has a p-type well PWL, a body contact region BC, a source region SR, a plug PLG, a trench TR, a gate insulating film GOX, and a gate electrode GE. The sense transistor ST includes the cell transistor ST2 and the cell transistor ST3. The substrate SUB and the epitaxial layer EPI function as the drain region of the sense transistor ST.

The trench TRC is formed in the epitaxial layer EPI. The gate electrode GE is formed in the trench TRC via the gate insulating film GOX. The trench TRD is formed in the epitaxial layer EPI. The gate electrode GE is formed in the trench TRD via the gate insulating film GOX.

The p-type well PWL is formed in the epitaxial layer EPI. The source region SR is formed in the p-type well PWL. The source region SR is disposed between the trench TRC and the trench TRD. The source region SR of the cell transistor ST2 is formed at a position opposite to the source region SRD of the dummy transistor DT1 relative to the trench TRC. The source region SR of the cell transistor ST2 is in contact with the trench TRC and the trench TRD.

The body contact region BC is formed in the p-type well PWL. The plug PLG is formed to be contact with the source region SR and the body contact region BC. The plug PLG is formed to penetrate through the source region SR and reach the body contact region BC. The source region SR and the body contact region BC are electrically connected to each other by the plug PLG. The source region SR and the body contact region BC are electrically connected to the pad PD, which is a sense terminal IS.

The gate electrode GE of the dummy transistor DT1 and the gate electrode GE of the sense transistor ST are electrically connected to each other. In the X direction, the sense transistor ST is disposed between the dummy transistor DT1 and the dummy transistor DT2.

The p-type well PWL, the body contact region BC, the source region SR, and the plug PLG of the cell transistor ST3 are formed between the trench TRD and the trench TRE. Regarding other configurations, the cell transistor ST3 has a similar configuration to the cell transistor ST2.

From the above, the source region SR of the sense transistor ST is electrically connected to the pad PD, which is a sense terminal IS. Thus, the source region SR of the sense transistor ST can be connected to the current detection part via the pad PD.

In contrast, the source region SRD of the dummy transistor DT1 is electrically connected to ground via the p-type transistor PQ2. This indicates that the source region SRD of the dummy transistor DT1 is electrically isolated from the source region SR of the sense transistor ST. In other words, the source region SRD of the dummy transistor DT1 is isolated from the current detection part.

The anode region of the diode D1 is electrically connected, for example, to the source region SR of the sense transistor ST. Namely, the anode region of the diode D1 is electrically connected to the pad PD, which is the sense terminal IS.

However, the anode region of the diode D1 may be electrically connected to, for instance, the source region SRD of the dummy transistor DT1. In other words, the anode region of the diode D1 may be electrically connected to ground via the p-type transistor PQ2.

Note that although the main transistor is not shown in FIG. 8, it has the following configuration. Namely, the main transistor includes a trench, a gate insulating film, a gate electrode, and a source region. The trench is formed in the semiconductor substrate 1S. The trench is disposed at the upper surface of the semiconductor substrate 1S. The gate electrode is formed in the trench via the gate insulating film. The source region is formed in the epitaxial layer EPI. The source region is disposed at the upper surface of the semiconductor substrate 1S. The source region is in contact with the trench.

### Features in Embodiment

The present inventor has newly discovered that the threshold voltage of the cell transistor ST1 adjacent to the diode is lower than the threshold voltage of the cell transistor ST2 and the cell transistor ST3. Based on this finding, the embodiment applies the basic idea to the cell transistor ST1 adjacent to the diode. That is, the feature in the embodiment is to make the cell transistor ST1 adjacent to the diode a dummy transistor DT.

Therefore, in the embodiment, the source region of the cell transistor ST1 adjacent to the diode is electrically isolated from the source regions of other cell transistors constituting the sense transistor ST.

Specifically, "other cell transistors" refer to, for example, the cell transistor ST2 and the cell transistor ST3 shown in FIG. 8. The source regions SR of the cell transistor ST2 and the cell transistor ST3 are electrically connected to the pad PD, which is the sense terminal IS.

In contrast, as shown in FIG. 8, the cell transistor ST1 adjacent to the diode is electrically connected to ground via the p-type transistor PQ2. As a result, the cell transistor ST1 adjacent to the diode becomes the dummy transistor DT, which does not function as a sense transistor.

Thus, according to the embodiment, the cell transistor ST1 is not used as the sense transistor ST for detecting the current flowing through the main transistor MT. In other words, in the embodiment, the cell transistor ST1 is the dummy transistor DT. Since the cell transistor ST1 is not used as the sense transistor ST, the threshold voltage variation of "other cell transistors" becomes smaller. Therefore, the threshold voltage of the sense transistor ST becomes close to the threshold voltage of the main transistor MT. Thus, "ΔVth" can be reduced.

### Modified Example

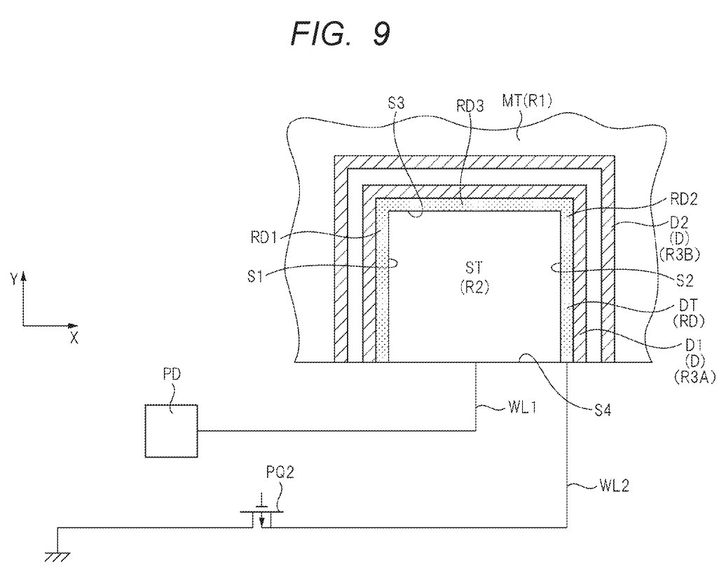

FIG. 9 is an enlarged view of the vicinity of the sense transistor formation region R2.

FIG. 9 is a modified example of FIG. 7.

The planar shape of the sense transistor formation region R2 is rectangular. The rectangle has a first side S1, a second side S2, a third side S3, and a fourth side S4.

In the modified example, the dummy transistor formation region RD includes a dummy transistor formation region RD1, a dummy transistor formation region RD2, and a dummy transistor formation region RD3. The dummy transistor formation region RD1 is in contact with the first side S1. The dummy transistor formation region RD2 is in contact with the second side S2. The dummy transistor formation region RD3 is in contact with the third side S3.

In the modified example, the dummy transistor formation region RD3 is formed in addition to the dummy transistor formation region RD1 and the dummy transistor formation region RD2. This is the main difference between the embodiment shown in FIG. 7 and the modified example shown in FIG. 9.

As shown in FIG. 9, in the Y direction orthogonal to the X direction, the dummy transistor DT formed in the dummy transistor formation region RD3 is disposed adjacent to the sense transistor ST. A current blocking part is formed between the dummy transistor DT and the sense transistor ST in the dummy transistor formation region RD3. The dummy transistor DT and the sense transistor ST in the dummy transistor formation region RD3 are electrically isolated by the current blocking part.

The current blocking part can be configured by, for example, a blocking trench. Below, an example of constituting the current blocking part from a blocking trench will be explained.

In the dummy transistor formation region RD1, the trench extends in the Y direction. Moreover, the dummy transistor DT and the sense transistor ST are arranged side by side in the X direction. Therefore, the dummy transistor DT formed in the dummy transistor formation region RD1 can be electrically isolated from the sense transistor ST by the trench.

In the dummy transistor formation region RD2, the trench extends in the Y direction. Moreover, the dummy transistor DT and the sense transistor ST are arranged side by side in the X direction. Therefore, the dummy transistor DT formed in the dummy transistor formation region RD2 can be electrically isolated from the sense transistor ST by the trench.

In contrast, in the dummy transistor formation region RD3, the trench extends in the Y direction. The dummy transistor DT and the sense transistor ST are arranged side by side in the Y direction. Thus, in the dummy transistor formation region RD3, the dummy transistor DT cannot be electrically isolated from the sense transistor ST by the trench.

Therefore, in the modified example, a current blocking part is formed between the dummy transistor DT and the sense transistor ST in the dummy transistor formation region RD3. For example, the current blocking part is configured by a blocking trench. The blocking trench extends in the X direction. The blocking trench connects the plurality of trenches extending in the Y direction. The dummy transistor DT and the sense transistor ST in the dummy transistor formation region RD3 are electrically isolated by the current blocking part.

In the modified example, the source region of the sense transistor ST is electrically connected to the pad PD via the wiring line WL1. The source region of the dummy transistor DT is electrically connected to ground via the wiring line WL2 and the p-type transistor PQ2. In the modified example, the wiring line WL1 and the wiring line WL2 do not intersect. Therefore, in the modified example, both the wiring line WL1 and the wiring line WL2 can be formed in the wiring of the same wiring layer. For instance, each of wiring line WL1 and wiring line WL2 can be formed as the first layer wiring, which is the lowest layer wiring.

The invention made by the present inventor has been described above in detail based on the embodiment, but the present invention is not limited to the embodiment described above, and it is needless to say that various modified examples can be made without departing from the gist thereof.

What is claimed is:

1. A semiconductor device comprising:
a main transistor;
a diode;
a first transistor; and
a second transistor,
wherein in a first direction, the first transistor is disposed between the diode and the second transistor,
wherein the first transistor comprises a first gate electrode and a first source region,
wherein the second transistor comprises a second gate electrode and a second source region,
wherein the first gate electrode and the second gate electrode are electrically connected to each other, and
wherein the first source region and the second source region are electrically isolated from each other.

2. The semiconductor device according to claim 1,
wherein the second transistor is configured to detect a current flowing through the main transistor.

3. The semiconductor device according to claim 1,
wherein the main transistor is a field-effect transistor,
wherein a gate length of the main transistor is equal to a gate length of the first transistor,
wherein the gate length of the main transistor is equal to a gate length of the second transistor,
wherein a gate width of the first transistor is smaller than a gate width of the main transistor,
wherein a gate width of the second transistor is smaller than the gate width of the main transistor, and
wherein the gate width of the first transistor is equal to or smaller than the gate width of the second transistor.

4. The semiconductor device according to claim 1, comprising:
a control circuit,
wherein the control circuit is configured to control an operation of each of the main transistor, the first transistor, and the second transistor,
wherein the control circuit comprises a transistor, and
wherein the first source region is connected to ground via the transistor.

5. The semiconductor device according to claim 4, comprising:
a current detection part,
wherein the current detection part is configured to detect a current flowing through the main transistor based on a current flowing through the second transistor, and
wherein the second source region is electrically connected to the current detection part.

6. The semiconductor device according to claim 5,
wherein the first source region is electrically isolated from the current detection part.

7. The semiconductor device according to claim 1,
wherein the second source region is electrically connected to a pad, which is an external connection terminal.

8. The semiconductor device according to claim 1, comprising:
a third transistor,
wherein the third transistor comprises a third gate electrode and a third source region,
wherein the first gate electrode, the second gate electrode, and the third gate electrode are electrically connected to each other,
wherein the second source region and the third source region are electrically isolated from each other, and
wherein in the first direction, the second transistor is disposed between the first transistor and the third transistor.

9. The semiconductor device according to claim 8, comprising:
a fourth transistor,
wherein the fourth transistor comprises a fourth gate electrode and a fourth source region,
wherein the first gate electrode, the second gate electrode, the third gate electrode, and the fourth gate electrode are electrically connected to each other,
wherein the second source region and the fourth source region are electrically isolated from each other,
wherein in a second direction orthogonal to the first direction, the fourth transistor is disposed adjacent to the second transistor,
wherein a current blocking part is formed between the second transistor and the fourth transistor, and
wherein the second transistor and the fourth transistor are electrically isolated from each other by the current blocking part.

10. The semiconductor device according to claim 1,
wherein the diode comprises an anode region and a cathode region, and
wherein the anode region is electrically connected to the first source region.

11. The semiconductor device according to claim 1,
wherein the diode comprises an anode region and a cathode region, and
wherein the anode region is electrically connected to the second source region.

12. The semiconductor device according to claim 1,
wherein the diode has a function of suppressing parasitic bipolar transistor operation.

13. The semiconductor device according to claim 1,
wherein the diode comprises an anode region and a cathode region,
wherein the semiconductor device comprises:
a semiconductor substrate having a first surface and a second surface opposite the first surface, the semiconductor substrate comprising a substrate and an epitaxial layer formed on the substrate;
a drain electrode formed on the second surface; and
a plurality of trenches formed in the epitaxial layer and disposed at the first surface,
wherein the plurality of trenches comprise a first trench, a second trench, and a third trench,
wherein the first trench, the second trench, and the third trench are arranged in the first direction,
wherein the second trench is disposed between the first trench and the third trench,
wherein in plan view, the diode surrounds the first transistor and the second transistor,
wherein the anode region is formed in the epitaxial layer and disposed between the first trench and the second trench,
wherein a portion of the epitaxial layer located under the anode region functions as the cathode region,
wherein the first gate electrode is formed in the second trench via a first gate insulating film,
wherein the second gate electrode is formed in the third trench via a second gate insulating film,
wherein the first source region is formed in the epitaxial layer and disposed between the second trench and the third trench,
wherein the second source region is formed in the epitaxial layer,
wherein the anode region and the first source region are in contact with the second trench, and
wherein the first source region and the second source region are in contact with the third trench.

14. The semiconductor device according to claim 13, comprising:
a fourth transistor,
wherein the fourth transistor comprises a fourth gate electrode and a fourth source region,
wherein the first gate electrode, the second gate electrode, and the fourth gate electrode are electrically connected to each other,
wherein the second source region and the fourth source region are electrically isolated from each other,
wherein in a second direction orthogonal to the first direction, the fourth transistor is disposed adjacent to the second transistor,
wherein a blocking trench extending in the first direction is formed between the second transistor and the fourth transistor, and
wherein the second transistor and the fourth transistor are electrically isolated from each other by the blocking trench.

15. The semiconductor device according to claim 1,
wherein in plan view, a size of the main transistor is larger than a size of the second transistor.

16. The semiconductor device according to claim 13,
wherein the main transistor comprises:
a fourth trench formed in the semiconductor substrate and disposed at the first surface;
a fifth gate electrode formed in the fourth trench via a third gate insulating film; and
a fifth source region formed in the epitaxial layer, disposed at the first surface, and being in contact with the fourth trench.

17. A semiconductor device comprising:
a main transistor;
a first transistor; and
a second transistor,
wherein the first transistor comprises a first gate electrode and a first source region,
wherein the second transistor comprises a second gate electrode and a second source region,
wherein the first gate electrode and the second gate electrode are electrically connected to each other,
wherein the first transistor has a lower threshold voltage than the second transistor, and
wherein the first source region and the second source region are electrically isolated from each other.
